(19) United States
(12) Patent Application Publication
(10) Pub. No.: US 2006/0094210 A1
(43) Pub. Date: May 4, 2006

(54) Semiconductor wafer processing method and processing apparatus

(76) Inventor: Keiichi Kajiyama, Tokyo (JP)

Correspondence Address: SMITH, GAMBRELL & RUSSELL, LLP, 1850 M STREET, N.W., SUITE 800, WASHINGTON, DC, 20036, US

(21) Appl. No.: 11/300,507

(22) Filed: Dec. 15, 2005

Related U.S. Application Data
(62) Division of application No. 10/934,553, filed on Sep. 7, 2004, now abandoned.

(30) Foreign Application Priority Data
Sep. 8, 2003 (JP) 2003-315164

(51) Int. Cl. H01L 21/78

(52) U.S. Cl. 438/460

(57) ABSTRACT

A method of processing a semiconductor wafer having circuits which are formed in a plurality of rectangular areas sectioned by streets arranged in a lattice pattern on the front surface, comprising: a grinding step of grinding the back surface of the semiconductor wafer to a predetermined thickness; and an oxide film forming step of forming an oxide film on the back surface of the semiconductor wafer ground to the predetermined thickness.

### FIELD OF THE INVENTION

The present invention relates to a method of processing a semiconductor wafer to a predetermined thickness and to a processing apparatus.

### DESCRIPTION OF THE PRIOR ART

In the manufacture of a semiconductor device, a large number of rectangular areas are defined by cutting lines called “streets” arranged in a lattice pattern on the front surface of a substantially disk-like semiconductor wafer and a circuit such as IC or LSI is formed in each of the rectangular areas. Individual semiconductor chips are formed by dividing this semiconductor wafer having a large number of circuits formed thereon, along the streets. The semiconductor chips are widely used in electric equipment such as portable telephones and personal computers. In general, for the downsizing of the semiconductor chips, the back surface of the semiconductor wafer is ground to a predetermined thickness (for example, 30 to 100 μm) before the semiconductor wafer is cut along the streets to be divided into the rectangular areas.

As a processing technology for forming thin semiconductor chips, a dividing method so called “pre-dicing” is practically used. This dicing is a technology for forming cutting grooves having a predetermined depth corresponding to the final thickness of each chip along streets formed on the front surface of a semiconductor wafer, and polishing the back surface of the wafer until the cutting grooves are exposed to divide the semiconductor wafer into individual semiconductor chips.

When the back surface of the semiconductor wafer is ground as described above, a plurality of micro-cracks are produced on the ground surface, thereby reducing the breaking strength of the semiconductor chips. Therefore, after the back surface of the semiconductor wafer is ground, the ground surface is polished or etched to remove the micro-cracks.

When the back surface of the semiconductor wafer, particularly a silicon wafer, is ground, polished or etched to expose the silicon raw material surface, that is, the pure surface, metal ions which have entered the interior of a silicon substrate at the time of forming a circuit such as IC or LSI freely move to act on the circuit, thereby impairing the function of the circuit. When the silicon raw material surface, that is, the pure surface is exposed, impurities contained in the air enter the interior of the silicon substrate from the exposed pure surface to deteriorate the semiconductor wafer, that is, the semiconductor chips.

### SUMMARY OF THE INVENTION

It is an object of the present invention to provide a semiconductor wafer processing method and processing apparatus which can restrict the movement of metal ions which have entered the interior of a substrate and can prevent impurities contained in the air from entering the interior of the substrate even when the back surface of the semiconductor wafer is ground to a predetermined thickness.

To attain the above object, according to the present invention, there is provided a method of processing a semiconductor wafer having circuits which are formed in a large number of rectangular areas sectioned by streets arranged in a lattice pattern on the front surface, comprising:

a grinding step of grinding the back surface of the semiconductor wafer to a predetermined thickness; and

an oxide film forming step of forming an oxide film on the back surface of the semiconductor wafer ground to the predetermined thickness.

Preferably, after the above grinding step, a polishing step of polishing the back surface of the semiconductor wafer ground to the predetermined thickness to remove micro-cracks is carried out. Preferably, after the above grinding step, an etching step of etching the back surface of the semiconductor wafer ground to the predetermined thickness to remove the micro-cracks is carried out.

Before the above grinding step, a dividing groove forming step of forming dividing grooves having a predetermined depth corresponding to the final thickness along the streets formed on the front surface of the semiconductor wafer is carried out.

Further, according to the present invention, there is provided a processing apparatus which comprises a chuck table for holding a workpiece, a grinding means for grinding the workpiece held on the chuck table, and an oxide film forming means for forming an oxide film on the ground surface of the workpiece ground by the grinding means.

Preferably, the processing apparatus further comprises a polishing means for polishing the ground surface of the workpiece ground by the grinding means to remove micro-cracks. Preferably, the processing apparatus further comprises an etching means for etching the ground surface of the workpiece ground by the grinding means to remove micro-cracks.

Since an oxide film is formed on the back surface of the semiconductor wafer after the back surface of the semiconductor wafer is ground to a predetermined thickness in the method of processing a semiconductor wafer of the present invention, this oxide film can restrict the movement of metal ions which have entered the interior of a silicon substrate constituting the semiconductor wafer when circuits are formed on the front surface of the semiconductor wafer, and can prevent impurities contained in the air from entering the interior of the silicon substrate.

Since the step of forming an oxide film is carried out by oxide film forming means right after the pure surface is exposed by carrying out the grinding step in the processing apparatus constituted according to the present invention, the influence of the above metal ions and impurities can be suppressed as much as possible.

### BRIEF DESCRIPTION OF THE DRAWINGS

FIG. 1 is a perspective view of a processing apparatus according to a first embodiment of the present invention;

FIG. 2 is a front view of a cleaning and oxide film forming means provided in the processing apparatus shown in FIG. 1;

FIG. 3 is a perspective view of a processing apparatus according to a second embodiment of the present invention; and

FIG. 4 is a sectional view of an etching and oxide film forming means provided in the processing apparatus shown in FIG. 3.

### DETAILED DESCRIPTION OF THE PREFERRED EMBODIMENTS

A semiconductor wafer processing method and processing apparatus according to preferred embodiments of the present invention will be described in detail herein below with reference to the accompanying drawings.

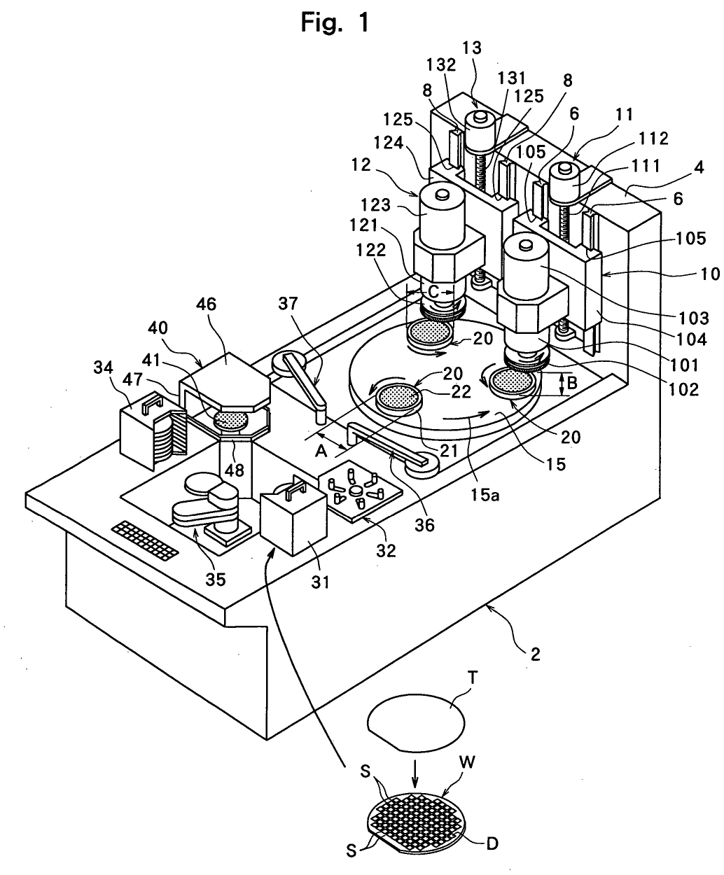

FIG. 1 is a perspective view of a semiconductor processing apparatus according to a first embodiment of the present invention.

The processing apparatus in the illustrated embodiment has a substantially rectangular parallelepiped housing 2. A stationary support board 4 projects upright from the right upper end in FIG. 1 of the housing 2. On the inner flank of this stationary support board 4, two pairs of guide rails 6, 6 and 8, 8 extending in a vertical direction are installed. A grinding unit 10 as the grinding means is mounted on one pair of guide rails 6, 6 in such a manner that it can move in the vertical direction, and a polishing unit 12 as the polishing means is mounted on the other pair of guide rails 8, 8 in such a manner that it can move in the vertical direction.

The grinding unit 10 comprises a unit housing 101, a grinding wheel 102 rotatably mounted to the lower end of the unit housing 101, a servomotor 103, mounted to the upper end of the unit housing 101, for rotating the grinding wheel 102 in a direction indicated by an arrow, and a movable base 104 for mounting the unit housing 101. The movable base 104 is provided with guide rails 105, 105. The grinding unit 10 can be moved in the vertical direction by movably fitting the guide rails 105, 105 to the guide rails 6, 6 on the stationary support board 4. The grinding unit 10 in the illustrated embodiment comprises a feed mechanism 11 for moving the above movable base 104 along the guide rails 6, 6 to adjust the cutting depth of the grinding wheel 102. The feed mechanism 11 comprises a male screw rod 111 which is rotatably supported to the above stationary support board 4 and arranged parallel to the guide rails 6, 6 in the vertical direction, a pulse motor 112 for driving the male screw rod 111, and a female screw block (not shown) which is screwed on the male screw rod 11 and mounted to the above movable base 104. By driving the male screw rod 111 in a normal direction or opposite direction with the pulse motor 112, the grinding unit 10 is moved in the vertical direction.

The above polishing unit 12 is constituted the same as the above grinding unit 10 except for the above grinding wheel 102. That is, the polishing unit 12 comprises a unit housing 121, a polishing tool 122 rotatably mounted to the lower end of the unit housing 121, a rotary drive mechanism 123, mounted to the upper end of the unit housing 121, for rotating the polishing tool 122 in a direction indicated by an arrow, and a movable base 124 for mounting the unit housing 121. This movable base 124 is provided with guide rails 125, 125. The polishing unit 12 can be moved in the vertical direction by movably fitting the guide rails 125, 125 to the guide rails 8, 8 on the above stationary support board 4. The polishing unit 12 in the illustrated embodiment comprises a feed mechanism 13 for moving the above movable base 124 along the guide rails 8, 8 to adjust the pressure to a workpiece of the polishing tool 122. This feed mechanism 13 is substantially constituted the same as the above feed mechanism 11. That is, the feed mechanism 13 comprises a male screw rod 131 which is rotatably supported to the above stationary support board 4 and arranged parallel to the guide rails 8, 8 in the vertical direction, a pulse motor 132 for driving the male screw rod 131, and a female screw block (not shown) which is fitted to the male screw rod 131 and mounted to the above movable base 124. By driving the male screw rod 131 in a normal direction or opposite direction with the pulse motor 132, the polishing unit 12 is moved in the vertical direction. As the above polishing tool 122 is used a felt whetstone formed by dispersing abrasive grains in felt and fixing them with a suitable adhesive in the illustrated embodiment. A detailed description of the polishing tool 122 composed of this felt whetstone is given in JP-A 2002-283243 proposed by the present applicant and therefore is omitted in this specification.

The processing apparatus in the illustrated embodiment comprises a turntable 15 which is substantially flush with the top surface of the housing 2 and arranged in front of the above stationary support board 4. This turntable 15 is formed like a disk having a relatively large diameter and suitably rotated in a direction indicated by an arrow 15a by a drive mechanism that is not shown. Three chuck tables 20 as semiconductor wafer mounting members are rotatably mounted on the turntable 15 at a phase angle of 120° on a horizontal plane in the illustrated embodiment. Each of the chuck tables 20 comprises a disk-like base 21 having a circular recessed portion with an open top and an adsorption-holding chuck 22 which is composed of a porous ceramic board and fitted in the recessed portion formed in the base 21 and is rotated in a direction indicated by an arrow by a drive mechanism that is not shown. The chuck table 20 is connected to a suction means that is not shown. The three chuck tables 20 mounted on the turntable 15 constituted as described above are moved to a workpiece take-in/take-out area A, grinding area B and polishing area C and workpiece take-in/take-out area A sequentially by the rotation of the turntable 15.

An unprocessed wafer cassette 31 for storing a semiconductor wafer before processing and a temporary storage table 32 as a semiconductor wafer mounting member interposed between the unprocessed wafer cassette 31 and the workpiece take-in/take-out area A abackranged on one side of the workpiece take-in/take-out area A in the illustrated processing apparatus The semiconductor wafer W is stored in the unprocessed wafer cassette 31. A large number of rectangular areas are sectioned by streets S arranged in a lattice pattern on the front surface of the semiconductor wafer W, and a circuit D is formed in each of the sectioned rectangular areas. This semiconductor wafer W is stored in such a manner that a protective tape T is affixed to its front surface and its back surface faces up. The step of forming dividing grooves having a predetermined depth corresponding to the final thickness along the streets S in the front surface of the semiconductor wafer W may be carried out on the semiconductor wafer W before the protective tape T is affixed to the front surface of the semiconductor wafer W. A so-called dicing tape affixed to an annular frame may be used as the protective tape T.

On the other side of the workpiece take-in/take-out area A of the processing apparatus, a cleaning and oxide film forming means 40 for cleaning the semiconductor wafer after grinding and polishing and forming an oxide film on the back surface of the semiconductor wafer is arranged. The cleaning and oxide film forming means 40 will be described in detail later on. On the other side of the workpiece take-in/take-out area A, a processed wafer cassette 34 for storing the semiconductor wafer W after processing cleaned and having an oxide film formed on the back surface by the above cleaning and oxide film forming means 40 is also arranged.

The processing apparatus in the illustrated embodiment comprises a workpiece conveying mechanism 35 for taking out the semiconductor wafer W stored in the unprocessed wafer cassette 31 to the temporary storage table 32 and carrying the semiconductor wafer W cleaned and having an oxide film formed on the back surface by the cleaning and oxide film forming means 40 to the processed wafer cassette 34. The processing apparatus in the illustrated embodiment comprises a workpiece take-in mechanism 36 for carrying the semiconductor wafer W before processing placed on the above temporary storage table 32 to the top of a chuck table 20 positioned in the workpiece take-in/take-out area A and a workpiece take-out mechanism 37 for carrying the semiconductor wafer W after processing that is placed on a chuck table 20 positioned in the workpiece take-in/take-out area A to the cleaning and oxide film forming means 40.

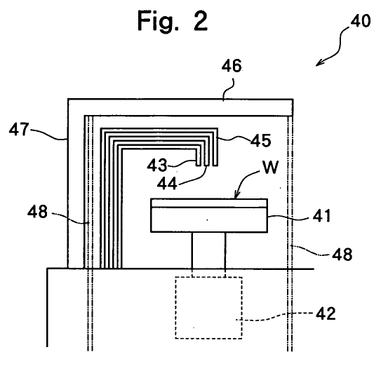

The above cleaning and oxide film forming means 40 will be described with reference to FIG. 2.

The cleaning and oxide film forming means 40 in the illustrated embodiment comprises a spinner table 41 for suction-holding the semiconductor wafer W after grinding or grinding and polishing, an electric motor 42 for driving the spinner table 41, a wash water nozzle 43 for supplying wash water to the semiconductor wafer W held on the spinner table 41, an air nozzle 44 for supplying air for drying to the semiconductor wafer W held on the spinner table 41, and an oxidizing liquid nozzle 45 for supplying an oxidizing liquid to the semiconductor wafer W held on the spinner table 41. The wash water nozzle 43 is connected to a wash water supply means (not shown), the air nozzle 44 is connected to an air supply means (not shown), and the oxidizing liquid nozzle 45 is connected to a hydrogen peroxide (H₂O₂) supply means that is not shown. The cleaning and oxide film forming means 40 in the illustrated embodiment comprises a ceiling wall 46 for covering the spinner table 41 and the top portions of the wash water nozzle 43, the air nozzle 44 and the oxidizing liquid nozzle 45 and a side wall 46 for covering one side (left in FIG. 2), and a shutter 48 for covering sides other than the one side (left in FIG. 2) as required.

The processing apparatus in the illustrated embodiment is constituted as described above and its operation will be described hereinbelow.

The semiconductor wafer W before processing having a tape T affixed to the front surface is stored in the unprocessed wafer cassette 31 in such a manner that the protective tape T faces down, that is, the back surface faces up. The semiconductor wafer W before processing stored in the unprocessed wafer cassette 31 is carried and mounted on the temporary storage table 32 by the vertical movement and turning movement of the workpiece conveying means 35. The semiconductor wafer W before processing mounted on the temporary storage table 32 is centered by the radial movements toward the center of six pins, for example. The centered semiconductor wafer W mounted on the temporary storage table 32 is carried to the top of the chuck table 20 positioned in the workpiece take-in/take-out area A by the vertical movement and turning movement of the workpiece take-in means 36 in such a manner that the protective tape T faces down, that is, the back surface faces up. After the semiconductor wafer W before processing is placed on the chuck table 20, the suction means (not shown) is activated to suction-hold the semiconductor wafer W before processing on the adsorption-holding chuck 22. The turntable 15 is turned at 120° in the direction indicated by the arrow 15a by the drive mechanism (not shown) to move the chuck table 20 placing the semiconductor wafer W before processing to the grinding area B.

After the chuck table 20 placing the semiconductor wafer W before processing is moved to the grinding area B, it is turned in the direction indicated by the arrow by the drive mechanism (not shown), and the grinding wheel 102 of the grinding unit 10 is lowered a predetermined distance by the feed mechanism all while it is turned in the direction indicated by the arrow to grind the back surface of the semiconductor wafer W before processing on the chuck table 20. The semiconductor wafer W is thus ground to a predetermined thickness (grinding step). When dividing grooves having a predetermined depth corresponding to the final thickness have been formed along the streets S in the front surface of the semiconductor wafer W by carrying out the dividing groove forming step on the semiconductor wafer W, the above grinding step is carried out to expose the dividing grooves so as to divide the semiconductor wafer W into individual chips. Since the protective tape T is affixed to the semiconductor wafer W, the chips do not fall apart and the shape of the semiconductor wafer W is maintained. During this step, a semiconductor wafer W before processing is placed on the next chuck table 20 positioned in the workpiece take-in/take-out area A as described above. The turntable 15 is then turned at 120° in the direction indicated by the arrow 15a to move the chuck table 20 placing the ground semiconductor wafer W to the polishing area C. The next chuck table 20 placing the semiconductor wafer W before processing in the workpiece take-in/take-out area A is positioned to the grinding area B and a chuck table 20 after the next chuck table is positioned to the workpiece take-in/take-out area A.

As described above, the semiconductor wafer W before processing mounted on the chuck table 20 positioned in the grinding area B is ground by the grinding unit 10, and the ground semiconductor wafer W placed on the chuck table 20 positioned in the polishing area C is polished by the polishing unit 12. Micro-cracks produced by grinding are removed by thus polishing the ground semiconductor wafer W (polishing step). The polishing step may be carried out not only by dry polishing as in the illustrated embodiment but also by wet polishing (CPM).

Thereafter, the turntable 15 is turned at 120° in the direction indicated by the arrow 15a to position the chuck table 20 placing the polished semiconductor wafer W to the workpiece take-in/take-out area A. The chuck table 20 placing the semiconductor wafer W ground in the grinding area B is moved to the polishing area C, and the chuck table 20 placing the semiconductor wafer W before processing in the workpiece take-in/take-out area A is moved to the grinding area B.

The chuck table 20 returned to the workpiece take-in/take-out area A through the grinding area B and the polishing area C cancels the adsorption-holding of the polished semiconductor wafer W. The polished semiconductor wafer W whose adsorption-holding has been canceled on the chuck table 20 returned to the workpiece take-in/take-out area A is taken from the chuck table 20 and placed on the spinner table 41 of the cleaning and oxide film forming means 40 in such a manner that its back surface faces up by the vertical movement and turning movement of the workpiece take-out means 37. The polished semiconductor wafer W placed on the spinner table 41 is suction-held on the spinner table 41.

After the polished semiconductor wafer W is suction-held on the spinner table 41, the shutter 48 is moved up as shown by a two-dotted chain line in FIG. 2 to cover the spinner table 41, the wash water nozzle 43, the air nozzle 44 and the oxidizing liquid nozzle 45, the electric motor 42 is driven to turn the spinner table 31, and the wash water supply means (not shown) is activated to supply wash water which may be pure water from the wash water nozzle 43 to the top surface (back surface: ground and polished surface) of the semiconductor wafer W in order to remove contaminants adhered in the grinding and polishing steps (cleaning step). The cleaning step is carried out, for example, by rotating the spinner table 41 at 300 rpm and supplying wash water at a rate of 2 liters/min for 1 minute, for example.

After the cleaning step is carried out as described above, the electric motor 42 is driven to rotate the spinner table 41, and the air supply means is activated to supply air to the top surface (back surface) of the semiconductor wafer W held on the spinner table 41 from the air nozzle 44 in order to dry the semiconductor wafer W (drying step). The drying step is carried out, for example, by rotating the spinner table 41 at 1,000 rpm and supplying air at a rate of 10 liters/min for 20 seconds.

After the cleaning step and the drying step are carried out as described above, the step of forming an oxide film on the back surface of the semiconductor wafer W is carried out. That is, the electric motor 42 is driven to rotate the spinner table 41, and the hydrogen peroxide supply means (not shown) is activated to supply hydrogen peroxide (H₂O₂) to the top surface (back surface) of the semiconductor wafer held on the spinner table 41 from the oxidizing liquid nozzle 45. The oxide film forming step is carried out, for example, by rotating the spinner table 41 at 300 rpm and supplying hydrogen peroxide (H₂O₂) at a rate of 2 liters/min for 1 minute. By carrying out the above oxide film forming step, a 10 to 50 Å oxide film (SiO₂) is formed on the back surface of the semiconductor wafer W comprising a silicon substrate.

After the oxide film (SiO₂) is formed on the back surface of the semiconductor wafer W, the movement of metal ions which have entered the interior of the silicon substrate constituting the semiconductor wafer when circuits D are formed on the front surface of the semiconductor wafer W can be restricted, and impurities in the air can be prevented from entering the interior of the silicon substrate. Therefore, the reduction in the function of the circuits caused by the movement of metal ions in the interior of the silicon substrate and the deterioration in quality of the semiconductor wafer, that is, the semiconductor chips, caused by the entry of impurities in the air into the interior of the silicon substrate can be prevented. Particularly in the processing apparatus in the illustrated embodiment, since the oxide film forming step is carried out right after the pure surface is exposed by carrying out the grinding and polishing steps and the cleaning step and the drying step are carried out, the influence of the above metal ions and impurities can be suppressed as much as possible. An oxide film (SiO₂) is formed on the back surface and side surfaces of each individual chip by carrying out the oxide film forming step in the case where the semiconductor wafer W has been divided into individual chips by carrying out the above dividing groove forming step and the above grinding step on the semiconductor wafer W. Therefore, the effect of restricting the movement of the above metal ions and the effect of blocking impurities in the air are enhanced.

After the oxide film is formed on the back surface of the semiconductor wafer W by carrying out the oxide film forming step, the suction-holding of the semiconductor wafer W held on the spinner table 41 is canceled. After the formation of the oxide film, hydrogen peroxide (H₂O₂) is desirably removed from the back surface of the semiconductor wafer W by cleaning. Then, the semiconductor wafer W whose suction-holding on the spinner table 41 has been canceled is carried and stored in the processed wafer cassette 34 by the vertical movement and turning movement of the workpiece conveying means 35.

After the semiconductor wafer W having the oxide film formed on the back surface as described above is cleaned, it may be carried to the frame supporting step for putting the semiconductor wafer W to a protective tape affixed to an annular frame without storing it in the processed wafer cassette 34. The thickness of the semiconductor wafer W has been recently reduced to 100 μm or less in the above grinding step to reduce the thickness of each semiconductor chip. When this thin semiconductor wafer W is stored in the processed wafer cassette 34, there is a possibility that it may be curved to deteriorate its quality or broken. To cope with this, the frame supporting step for putting a semiconductor wafer whose thickness has been reduced to 100 μm or less in the grinding step to a protective tape affixed to an annular frame may be carried out in some cases. However, the back surface of the ground semiconductor wafer W is activated and hence, when it is put to the protective tape affixed to the annular frame right after grinding, it perfectly adheres closely to the tape and it is difficult to remove it from the protective tape. When it is removed from the protective tape by force, it is broken. On the other hand, since the oxide film forming step is carried out to form an oxide film on the back surface of the semiconductor wafer W after the back surface of the semiconductor wafer is ground in the above embodiment, even when it is put to the protective tape affixed to the annular frame, it does not perfectly adhere closely to the protective tape by the function of the oxide film and it is easy to remove it from the protective tape.

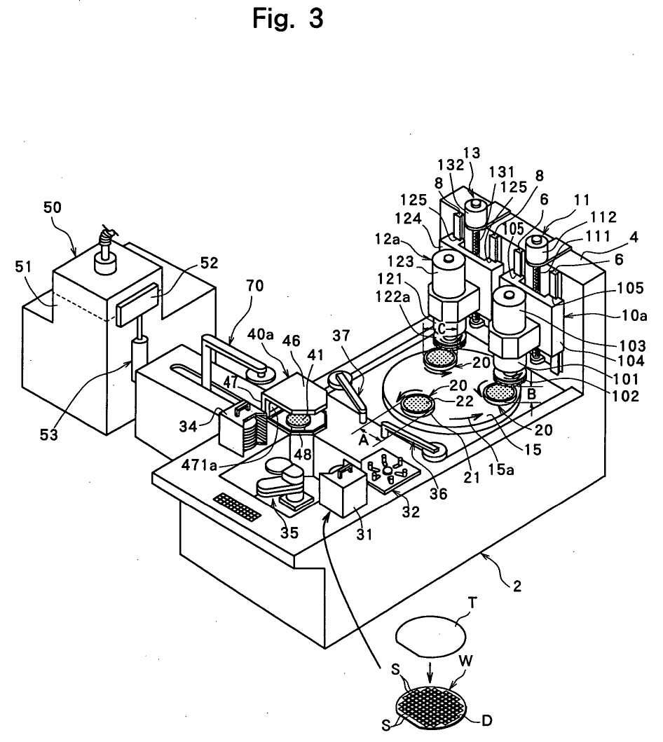

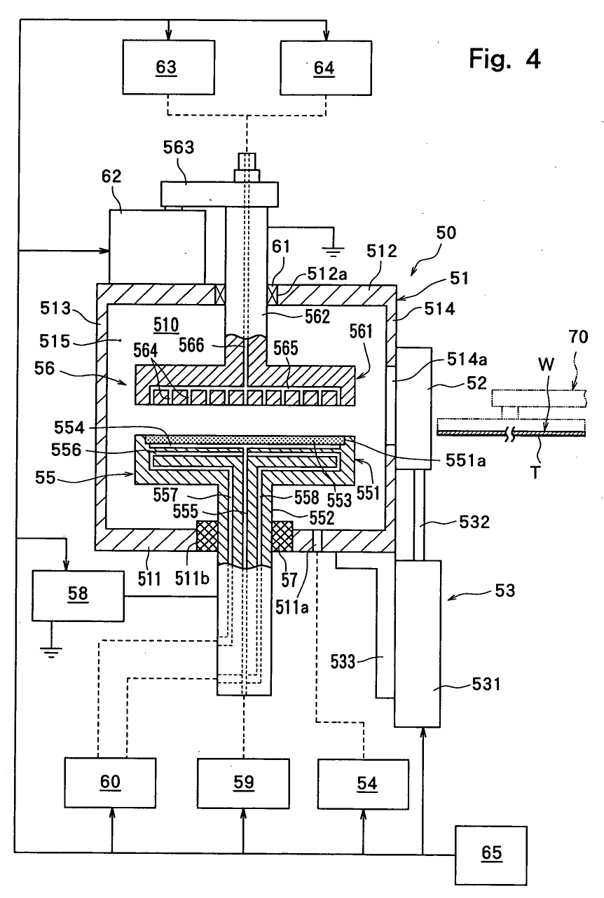

A description is subsequently given of a semiconductor wafer processing apparatus according to a second embodiment of the present invention with reference to FIG. 3 and FIG. 4. The processing apparatus according to the second embodiment shown in FIG. 3 and FIG. 4 is constructed by replacing the grinding unit 10 of the above first embodiment by a rough-grinding unit 10a, the polishing unit 12 by a finish-grinding unit 12a, and the cleaning and oxide film forming means 40 by a conventional cleaning means 40a having no function of forming an oxide film. Accordingly, as the second embodiment has substantially the same constitution as the first embodiment except that the polishing tool 122 of the polishing unit 12 of the first embodiment is changed to a grinding wheel 122a, the same members are given the same reference symbols and their descriptions are omitted. The processing apparatus according to the second embodiment comprises an etching and oxide film forming means 50 and a workpiece conveying means 70 which is interposed between the cleaning means 40a and the etching and oxide film forming means 50. Therefore, an opening 471a into which the workpiece conveying means 70 can be inserted is formed in the side wall 47 of the cleaning means 40a.

The above etching and oxide film forming means 50 will be described with reference to FIG. 4.

The etching and oxide film forming means 50 shown in FIG. 4 has a housing 51 forming a closed space 510. This housing 51 is composed of a bottom wall 511, top wall 512, left side 15 wall 513, right side wall 514, back side wall 515 and front side wall (not shown). An opening 514a for taking in and out the workpiece is formed in the right side wall 514. A gate 52 for opening and closing the opening 514a is provided outside the opening 514a in such a manner that it can move in the vertical direction. This gate 52 is moved by a gate moving means 53. The gate moving means 53 comprises an air cylinder 531 and a piston rod 532 connected to a piston (not shown) installed in the air cylinder 531. The air cylinder 531 is attached to the bottom wall 511 of the above housing 51 by a bracket 533, and the top end (upper end in the figure) of the piston rod 532 is connected to the above gate 52. By opening the gate 52 with this gate moving means 53, the semiconductor wafer W as the workpiece can be taken in and out through the opening 514a. An exhaust port 511a is formed in the bottom wall 511 constituting the housing 51 and connected to a gas exhaust means 54.

A lower electrode 55 and an upper electrode 56 are installed in the closed space 510 formed by the above housing 51 in such a manner that they are opposed to each other.

The lower electrode 55 is made of a conductive material and composed of a disk-like workpiece holding portion 551 and a columnar support portion 552 projecting from the center of the under surface of the workpiece holding portion 551. The lower electrode 55 composed of the workpiece holding portion 551 and the columnar support portion 552 as described above is supported to the bottom wall 511 in such a manner that the support portion 552 is sealed with the bottom wall 511 via an insulator 57 inserted into a hole 511b formed in the bottom wall 511 of the housing 51. The lower electrode 55 thus supported on the bottom wall 511 of the housing 51 is electrically connected to a high-frequency power supply 58 via the support portion 552.

A circular fitting recessed portion 551a having an open top is formed at the top of the workpiece holding portion 551 of the lower electrode 55, and a disk-like adsorption-holding member 553 made of a porous metal material is fitted in the fitting recessed portion 551a. A chamber 554 formed under the adsorption-holding member 553 in the fitting recessed portion 551a is connected to a suction means 59 through a communication path 555 formed in the workpiece holding portion 551 and the support portion 552. Therefore, when the workpiece is placed on the adsorption-holding member 553 and the suction means 59 is activated to connect the communication path 555 to a negative pressure source, a negative pressure is applied to the chamber 554 and the workpiece placed on the adsorption-holding member 553 is suction-held. When the suction means 59 is activated to open the communication path 555 to the air, the suction-holding of the workpiece suction-held on the adsorption-holding member 553 is canceled.

A cooling path 556 is formed in a lower part of the workpiece holding portion 551 of the lower electrode 55. One end of the cooling path 556 is connected to a refrigerant introduction path 557 formed in the support portion 552 and the other end of the cooling path 556 is connected to a refrigerant discharge path 558 formed in the support portion 552. The refrigerant introduction path 557 and the refrigerant discharge path 558 are connected to refrigerant supply means 60. Therefore, when the refrigerant supply means 60 is activated, a refrigerant is circulated through the refrigerant introduction path 557, cooling path 556 and refrigerant discharge path 558. As a result, heat generated by a plasma treatment is transmitted from the lower electrode 55 to the refrigerant, thereby making it possible to prevent an abnormal rise in the temperature of the lower electrode 55.

The above upper electrode 56 is made of a conductive material and composed of a disk-like gas ejection portion 561 and a columnar support portion 562 projecting from the center of the top surface of the gas ejection portion 561. The upper electrode 56 composed of the gas ejection portion 561 and the columnar support portion 562 is arranged such that the gas ejection portion 561 is opposed to the workpiece holding portion 551 constituting the lower electrode 55, and the support portion 562 is inserted into a hole 512a formed in the top wall 512 of the housing 51 and supported by a sealing member 61 mounted in the hole 512a in such a manner that it can move in the vertical direction. A working member 563 is mounted on the top end of the support portion 562 and connected to lifting drive means 62. The upper electrode 56 is grounded through the support portion 562.

A plurality of ejection ports 564 which are open to the under surface are formed in the disk-like gas ejection portion 561 constituting the upper electrode 56. The plurality of ejection ports 564 are connected to a gas supply means 63 and an ozone supply means 64 through a communicating path 565 formed in the gas ejection portion 561 and a communication path 566 formed in the support portion 562. The gas supply means 63 supplies a mixed gas for generating plasma, which is mainly composed of a fluorine-based gas such as CF₄ and oxygen. The ozone supply means 64 supplies ozone (O₂ or O₃).

The etching and oxide film forming means 50 in the illustrated embodiment comprises control means 65 for controlling the above gate moving means 53, gas exhaust means 54, high-frequency power supply 58, suction means 59, refrigerant supply means 60, lifting drive means 62, gas supply means 63 and ozone supply means 64. Data on the inside pressure of the closed space 510 formed by the housing 51, data on the temperature of the refrigerant (that is, the temperature of the electrode), data on the flow rate of the gas and data on the flow rate of ozone are input to the control means 65 from the gas exhaust means 54, the refrigerant supply means 60, the gas supply means 14 and the ozone supply means 64, respectively. The control means 65 outputs control signals to each of the above means based on the above data.

The semiconductor wafer processing apparatus according to the second embodiment shown in FIG. 3 and FIG. 4 is constituted as described above, and its operation will be described hereinunder.

The step of grinding the back surface of the semiconductor wafer W before processing having the protective tape T affixed to the front surface by the rough-grinding unit 10a is the same as in the above first embodiment. The step of finish-grinding the semiconductor wafer W roughly ground by the rough-grinding unit 10a is carried out by the finish-grinding unit 12a in the second embodiment. Therefore, in the second embodiment, the semiconductor wafer W is ground to a predetermined thickness by the grinding step consisting of rough-grinding and finish-grinding.

The semiconductor wafer W that has been ground to the predetermined thickness by the grinding step consisting of rough-grinding and finish-grinding is carried onto the top of the spinner table 41 of the cleaning means 40a. The same cleaning step and drying step as in the first embodiment are carried out on the semiconductor wafer W held on the spinner table 41.

The semiconductor wafer W cleaned and dried by the cleaning means 40a is carried to the etching and oxide film forming means 50 by the workpiece conveying means 70. At this point, the etching and oxide film forming means 50 activates the gate moving means 53 to move down the gate 52 in FIG. 4 to open the opening 514a formed in the right side wall 514 of the housing 51. The semiconductor wafer W carried by the workpiece conveying means 70 is carried into the closed space 510 formed by the housing 51 from the opening 514a with the back surface facing up and placed on the adsorption-holding member 553 of the workpiece holding portion 551 constituting the lower electrode 55. At this point, the lifting drive means 62 is activated to move up the upper electrode 56. Then, by operating the suction means 59 to apply negative pressure to the chamber 554, the semiconductor wafer W placed on the adsorption-holding member 553 is suction-held.

After the semiconductor wafer W is suction-held on the adsorption-holding member 553, the gate moving means 53 is activated to move up the gate 52 in FIG. 4 to close the opening 514a formed in the right side wall 514 of the housing 51. The lifting drive means 62 is then activated to lower the upper electrode 56 so as to position the distance between the under surface of the gas ejection portion 561 constituting the upper electrode 56 and the top surface (back surface to be etched) of the semiconductor wafer W held on the workpiece holding portion 551 constituting the lower electrode 55 to a predetermined value (for example, 10 mm) suitable for plasma etching.

The gas exhaust means 54 is then activated to evacuate the inside of the closed space 510 formed by the housing 51. After the inside of the closed space 510 is evacuated, the gas supply means 63 is activated to supply a mixed gas of a fluorine-based gas and oxygen gas as a plasma generating gas to the upper electrode 56. The mixed gas supplied from the gas supply means 63 is ejected from the plurality of ejection ports 564 to the top surface (back surface) of the semiconductor wafer W held on the adsorption-holding member 553 of the lower electrode 55 through the communication path 566 formed in the support portion 562 and the communication path 565 formed in the gas ejection portion 561. The inside of the closed space 510 is maintained at a predetermined gas pressure. A high-frequency voltage is applied between the lower electrode 55 and the upper electrode 56 from the high-frequency power supply 58 in a state of the mixed gas for generating plasma having been supplied. Thereby, plasma discharge is generated in the space between the lower electrode 55 and the upper electrode 56 so that the back surface of the semiconductor wafer W is etched by the function of an active substance produced by this plasma discharge (etching step). This plasma etching is continuously carried out until the thickness of the semiconductor wafer W becomes the target thickness, whereby micro-cracks produced in the back surface of the semiconductor wafer W by polishing are removed.

After the above etching step is carried out, the step of forming an oxide film on the back surface of the semiconductor wafer W is carried out. In this oxide film forming step, a mixed gas for generating plasma mainly composed of a fluorine-based gas such as CF₄ and oxygen is discharged by the gas exhaust means 54 and ozone (O₂ or O₃) is supplied from the ozone supply means 64 while a high-frequency voltage is applied between the lower electrode 55 and the upper electrode 56 as described above. The ozone supplied from the ozone supply means 64 is changed into plasma and ejected from the plurality of ejection ports 564 to the top surface (back surface) of the semiconductor wafer W held on the adsorption-holding member 553 of the lower electrode 55 through the communication path 566 formed in the support portion 562 and the communication path 565 formed in the gas ejection portion 561. As a result, an oxide film (SiO₂) is formed on the back surface of the semiconductor wafer W. The oxide film (SiO₂) thus formed on the back surface of the semiconductor wafer W prevents the reduction of the function of the circuits caused by the movement of metal ions which have entered the interior of the silicon substrate and blocks the entry of impurities in the air into the interior of the silicon substrate.

After the above oxide film forming step is carried out, ozone (O₂ or O₃) is discharged, the gate 52 is opened, and the workpiece conveying means 70 is activated to carry the semiconductor wafer W having the oxide film formed on the back surface to the top of the spinner table 41 of the cleaning means 40a. The semiconductor wafer W carried to the top of the spinner table 41 is carried and stored in the processed wafer cassette 34 by the vertical movement and turning movement of the workpiece conveying means 35.

In the above second embodiment, the plasma etching means for dry etching is used as the etching means but wet etching means may be employed. In this case, the above cleaning means 40a is provided with a means of supplying a hydrofluoric acid aqueous solution, for example, to supply a hydrofluoric acid aqueous solution to the top surface (back surface) of the semiconductor wafer W held on the spinner table 41 of the cleaning means 40a.

1-4. (canceled)

5. A processing apparatus comprising a chuck table for holding a workpiece, a grinding means for grinding the workpiece held on the chuck table, and an oxide film forming means for forming an oxide film on the ground surface of the workpiece ground by the grinding means.

6. The processing apparatus according to claim 5, which further comprises a polishing means for polishing the ground surface of the workpiece ground by the grinding means to remove micro-cracks.

7. The processing apparatus according to claim 5, which further comprises an etching means for etching the ground surface of the workpiece ground by the grinding means to remove micro-cracks.

8. The processing apparatus according to claim 6, which further comprises an etching means for etching the ground surface of the workpiece ground by the grinding means to remove micro-cracks.
